(19) United States
(12) Patent Application Publication
(10) Pub. No.: US 2026/0135570 A1
(43) Pub. Date: May 14, 2026

(54) METHOD AND DEVICE WITH COMPRESSION

(71) Applicant: Samsung Electronics Co., Ltd., Suwon-si (KR)

(72) Inventors: Jihye PARK, Suwon-si (KR); Jihoon NAM, Suwon-si (KR); Yeongon CHO, Suwon-si (KR); Yoojin KIM, Suwon-si (KR)

(73) Assignee: Samsung Electronics Co., Ltd., Suwon-si (KR)

(21) Appl. No.: 19/234,828

(22) Filed: Jun. 11, 2025

(30) Foreign Application Priority Data
Nov. 12, 2024 (KR) 10-2024-0160364

(51) Int. Cl. H03M 7/30

(52) U.S. Cl. CPC H03M 7/6011

(57) ABSTRACT

A processor-implemented method includes receiving original data, obtaining compressed data by compressing the original data, determining a compression performance index of the compressed data, determining whether to perform additional compression based on the compression performance index, in response to determining that the additional compression is to be performed, changing a compression parameter based on the compression performance index, and performing the additional compression on the compressed data based on the changed compression parameter.

### CROSS-REFERENCE TO RELATED APPLICATIONS

This application claims the benefit under 35 USC § 119(a) of Korean Patent Application No. 10-2024-0160364, filed on Nov. 12, 2024 in the Korean Intellectual Property Office, the entire disclosure of which is incorporated herein by reference for all purposes.

### BACKGROUND

### 1. Field

The following description relates to a method and device with compression.

### 2. Description of Related Art

Data processing and storage systems may require technology of efficiently storing and processing large amounts of data. Particularly, in high-performance computational tasks such as artificial intelligence (AI) and machine learning, memory capacity and performance are important factors. Various technologies have been introduced to increase memory capacity, but the cost burden and system complexity of processing large amounts of memory remain issues. Memory compression technology may be implemented to solve these issues.

Compression technology may efficiently expand memory capacity by compressing data and reducing memory usage. However, an additional issue of latency introduced during a process of decompressing the compressed data may affect performance. Typical memory compression methods have not effectively processed a trade-off between a compression ratio and decompression latency and thus, may not achieve optimal performance.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one or more general aspects, a processor-implemented method includes receiving original data, obtaining compressed data by compressing the original data, determining a compression performance index of the compressed data, determining whether to perform additional compression based on the compression performance index, in response to determining that the additional compression is to be performed, changing a compression parameter based on the compression performance index, and performing the additional compression on the compressed data based on the changed compression parameter.

The determining of whether to perform the additional compression may include comparing the compression performance index to a threshold value, and based on a result of the comparing, determining whether to perform the additional compression.

The determining of the compression performance index may include determining a compression ratio of the compressed data, and determining decompression latency of the compressed data.

The determining of whether to perform the additional compression may include comparing the compression ratio of the compressed data to a first threshold value, and comparing the decompression latency of the compressed data to a second threshold value.

The determining of whether to perform the additional compression may include determining not to perform the additional compression in response to the compression ratio being greater than the first threshold value and the decompression latency being less than or equal to the second threshold value.

The determining of whether to perform the additional compression may include determining to perform the additional compression in response to either one or both of the compression ratio being less than the first threshold value, and the decompression latency being greater than or equal to the second threshold value.

The determining of whether to perform the additional compression may include determining to perform the additional compression in response to the compression ratio being less than the first threshold value and the decompression latency being less than the second threshold value, and the changing of the compression parameter may include changing the compression parameter such that the compression ratio increases.

The determining of whether to perform the additional compression may include determining to perform the additional compression in response to the compression ratio being greater than or equal to the first threshold value and the decompression latency being greater than or equal to the second threshold value, and the changing of the compression parameter may include changing the compression parameter such that the compression latency decreases.

The determining of whether to perform the additional compression may include determining to perform the additional compression in response to the compression ratio being less than the first threshold value and the decompression latency being greater than or equal to the second threshold value, and the changing of the compression parameter may include determining a priority between the compression ratio and the decompression latency, and changing the compression parameter based on the priority.

The determining of the compression ratio may include determining the compression ratio by comparing a size of the original data to a size of the compressed data.

The determining of the decompression latency may include determining the decompression latency based on characteristics of a compression algorithm and a decompression device.

The changing of the compression parameter may include changing any one or any combination of any two or more of a compression algorithm, a compression performing unit, a match threshold, and a search window.

The changing of the compression parameter may include setting a combination of compression parameters based on any one or any combination of any two or more of a compression algorithm, a compression performing unit, a match threshold, and a search window, and determining the combination of compression parameters, based on the compression performance index.

In one or more general aspects, an electronic device includes one or more processors configured to receive original data, obtain compressed data by compressing the original data, determine a compression performance index of the compressed data, determine whether to perform additional compression based on the compression performance index, in response to determining that the additional compression is to be performed, change a compression parameter based on the compression performance index, and perform the additional compression on the compressed data based on the changed compression parameter.

For the determining of whether to perform the additional compression, the one or more processors may be configured to compare the compression performance index to a threshold value, and based on a result of the comparing, determine whether to perform the additional compression.

For the determining of the compression performance index, the one or more processors may be configured to determine a compression ratio of the compressed data, and determine decompression latency of the compressed data.

For the determining of whether to perform the additional compression, the one or more processors may be configured to compare the compression ratio of the compressed data to a first threshold value, and compare the decompression latency of the compressed data to a second threshold value.

For the determining of whether to perform the additional compression, the one or more processors may be configured to determine not to perform the additional compression in response to the compression ratio being greater than or equal to the first threshold value and the decompression latency being less than the second threshold value.

For the changing of the compression parameter, the one or more processors may be configured to set a combination of compression parameters based on any one or any combination of any two or more of a compression algorithm, a compression performing unit, a match threshold, and a search window, and determine the combination of the compression parameters based on the compression performance index.

In one or more general aspects, a processor-implemented method includes determining a compression ratio and a decompression latency of compressed data, in response to either one or both of the compression ratio being less than a first threshold value and the decompression latency being greater than or equal to a second threshold value, changing a compression parameter, and performing additional compression on the compressed data based on the changed compression parameter.

Other features and aspects will be apparent from the following detailed description, the drawings, and the claims.

### BRIEF DESCRIPTION OF THE DRAWINGS

FIG. 1 illustrates an example of a compression system.

FIG. 2 illustrates an example of a method of changing a compression parameter through a compression condition changing device.

FIG. 3 illustrates an example of a form of compressed data.

FIG. 4 illustrates an example of a configuration of a compression performance determination device.

FIG. 5 illustrates an example of performing iterative compression based on performance of a compression ratio and decompression latency.

FIG. 6 illustrates an example of performing iterative compression based on performance of a compression ratio and decompression latency.

FIG. 7 illustrates an example of a table representing a combination of compression parameters.

FIG. 8 illustrates an example of a compression method.

FIG. 9 illustrates an example of an electronic device.

Throughout the drawings and the detailed description, unless otherwise described or provided, the same drawing reference numerals will be understood to refer to the same elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a

comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

Although terms such as “first,” “second,” and “third,” or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but is used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

Throughout the specification, when a component or element is described as “on,” “connected to,” “coupled to,” or “joined to” another component, element, or layer, it may be directly (e.g., in contact with the other component, element, or layer) “on,” “connected to,” “coupled to,” or “joined to” the other component element, or layer, or there may reasonably be one or more other components elements, or layers intervening therebetween. When a component or element is described as “directly on,” “directly connected to,” “directly coupled to,” or “directly joined to” another component element, or layer, there can be no other components, elements, or layers intervening therebetween. Likewise, expressions, for example, “between” and “immediately between” and “adjacent to” and “immediately adjacent to” may also be construed as described in the foregoing.

The terminology used herein is for describing various examples only and is not to be used to limit the disclosure. The articles “a,” “an,” and “the” are intended to include the plural forms as well, unless the context clearly indicates otherwise. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof. Additionally, while one embodiment may set forth such terms “comprise” or “comprises,” “include” or “includes,” and “have” or “has” to specify the presence of stated features, numbers, operations, members, elements, and/or combinations thereof, other embodiments may exist where one or more of the stated features, numbers, operations, members, elements, and/or combinations thereof are not present.

Unless otherwise defined, all terms, including technical and scientific terms, used herein have the same meaning as commonly understood by one of ordinary skill in the art to which the present disclosure pertains and based on an understanding of the disclosure of the present application. Terms, such as those defined in commonly used dictionaries, should be construed to have meanings matching with contextual meanings in the relevant art and the disclosure of the present application, and are not to be construed to have an ideal or excessively formal meaning unless otherwise defined herein. The use of the term “may” herein with respect to an example or embodiment, e.g., as to what an example or embodiment may include or implement, means that at least one example or embodiment exists where such a feature is included or implemented, while all examples are not limited thereto. The use of the terms “example” or “embodiment” herein have a same meaning (e.g., the phrasing “in one example” has a same meaning as “in one embodiment,” and “one or more examples” has a same meaning as “in one or more embodiments”).

As used herein, the term “and/or” includes any one and any combination of any two or more of the associated listed items. The phrases “at least one of A, B, and C”, “at least one of A, B, or C”, and the like are intended to have disjunctive meanings, and these phrases “at least one of A, B, and C”, “at least one of A, B, or C”, and the like also include examples where there may be one or more of each of A, B, and/or C (e.g., any combination of one or more of each of A, B, and C), unless the corresponding description and embodiment necessitates such listings (e.g., “at least one of A, B, and C”) to be interpreted to have a conjunctive meaning.

The examples may be implemented as various types of products such as, for example, a personal computer, a laptop computer, a tablet computer, a smart phone, a television, a smart home appliance, an intelligent vehicle, a kiosk, and a wearable device. Hereinafter, examples will be described in detail with reference to the accompanying drawings. In the drawings, like reference numerals are used for like elements.

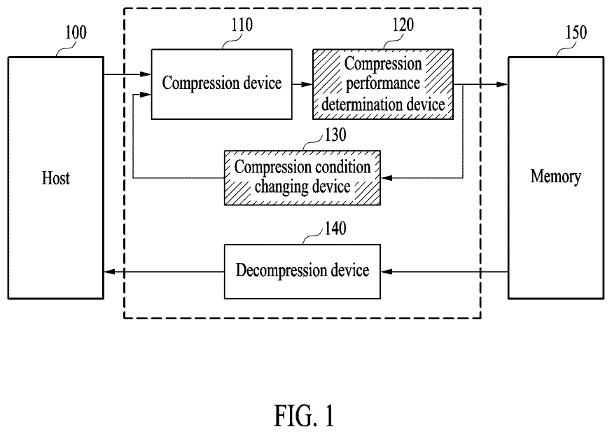

FIG. 1 illustrates an example of a compression system.

Referring to FIG. 1, the compression system according to an example may include a host 100, a compression device 110, a compression performance determination device 120, a compression condition changing device 130, a decompression device 140, and a memory 150 (e.g., one or more memories). However, not all the shown components are essential. The compression system may be implemented by more or less components than the illustrated components.

The host 100 may transmit original data to the compression device 110, and the compression device 110 may compress this data and store the data in the memory 150. Thereafter, when the host 100 is to use the compressed data, the compressed data may be restored to an original data form through the decompression device 140 and transmitted to the host 100.

Performance of the compression system according to an example may be evaluated based on a performance index. The performance index according to an example may be various numerical standards used to evaluate the performance of the compression system and may be an index indicating how efficiently data may be compressed and decompressed. The performance index may function to support optimization of the system by measuring compression quality, speed, and efficiency.

For example, the performance index may include a compression ratio, compression latency, and decompression latency. The compression ratio may be determined by comparing the size of the original data to the size of the compressed data. The compression ratio may be an important index indicating how efficiently the data has been compressed. The compression ratio may be the ratio between an uncompressed data size and a compressed data size. The higher the compression ratio, the smaller the compressed data is compared to the uncompressed data before compression (e.g., the more the data is compressed), which may help save memory space. The compression latency may refer to the time taken to compress the data. The decompression latency may refer to the time taken to restore the compressed data to the original form. Lower decompression latency may refer to faster data restoration, which may be a very important performance index for a system that requires real-time processing. The compression ratio, the compression latency, and the decompression latency may be in a relationship of trade-offs and may require different performance depending on characteristics of the system.

However, compression performance indices are not limited to the examples described above. Besides the compression ratio and the decompression latency, various other indices may be used to evaluate the performance of the compression system. For example, performance indices may include memory usage, which is the amount of memory resources that a system uses during compression and decompression processes, processing speed, which represents how fast a compression or decompression operation is performed, and in the case of lossy compression, compression quality, which measures the difference between original data and restored data after compression.

The compression system according to an example may be optimized by repeatedly performing compression until the performance index reaches a desired level.

To adjust the performance during the compression process, the compression performance determination device 120 according to an example may evaluate compression performance, may determine whether to perform additional compression, and when the additional compression is determined to be performed, may change a compression parameter through the compression condition changing device 130. Accordingly, iterative compression may be performed until factors such as the compression ratio and/or the decompression latency satisfy threshold values.

For example, the compression performance determination device 120 according to an example may determine the compression performance index of the compressed data and, based on the compression performance index, may determine whether to perform the additional compression. For example, the compression performance determination device 120 may determine to perform the additional compression when the compression ratio of the compressed data does not satisfy a predetermined standard. The maximum number of iterations and the threshold values of the performance indices used to determine whether to perform the additional compression may be transmitted and received through a special function register (SFR) according to an example.

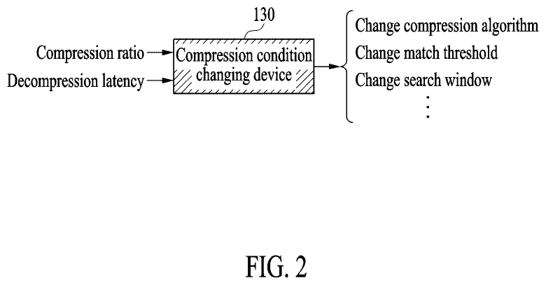

When the additional compression is determined to be performed, the compression condition changing device 130 according to an example may adjust various parameters to increase the compression ratio or reduce the decompression latency. Hereinafter, an example of a method of changing compression parameters through the compression condition changing device 130 is described in detail with reference to FIG. 2.

FIG. 2 illustrates an example of a method of changing a compression parameter through a compression condition changing device. The description provided with reference to FIG. 1 may also apply to FIG. 2.

Referring to FIG. 2, the compression condition changing device 130 according to an example may change a compression parameter value by considering a compression ratio and decompression latency.

A compression parameter according to an example may refer to variables used to adjust or optimize performance during data compression. The compression parameter may affect performance indices such as a compression ratio, processing speed, and decompression latency. Performance of a data compression system may be optimized by setting appropriate parameters.

The compression parameter according to an example may include at least one of a compression algorithm, a compression performing unit, a match threshold, and/or a search window.

The compression algorithm used may be a key parameter in the compression process. Since different compression algorithms may analyze and processes data patterns differently, it may be important to select an appropriate algorithm for particular data. The compression algorithm may include, for example, a Lempel-Ziv (LZ) algorithm, Huffman coding, and Burrows-Wheeler transform (BWT).

The compression performing unit according to an example may represent the size of data processed at one time when compressing data. A larger compression performing unit may result in a higher compression ratio but may increase decompression latency. On the contrary, a smaller compression performing unit may result in higher compression speed but may decrease the compression ratio.

The match threshold according to an example may be a parameter that specifies the minimum length of a duplicate data block for compression. A smaller match threshold may result in compression of shorter data duplication but may lower compression efficiency. On the contrary, a larger match threshold may result in higher compression efficiency, but compression may not be performed properly when there is little data duplication.

The search window according to an example may refer to the size of a data area in which data is searched for to find duplicate patterns during data compression. A larger search window may result in finding more duplicate data but may lower processing speed.

However, the compression parameters are not limited to the examples described above. In addition to the compression algorithm, the compression performing unit, the match threshold, and the search window, various indices may be used as the compression parameters. For example, the compression parameters may include a compression level, which is a parameter that adjusts the strength of data compression, a coding method, in which the coding method used in data compression is a compression parameter, and a data sampling ratio, which is a parameter that determines how finely data is sampled for compression.

The compression condition changing device 130 may dynamically change the compression parameters according to a degree to which the compression condition changing device 130 is to change the compression parameters by comparing the performance indices obtained after compression to the threshold value. For example, when the compression condition changing device 130 intends to increase the compression ratio, the compression condition changing device 130 may reduce the match threshold, may increase the size of the search window, and/or may change multiple parameters simultaneously.

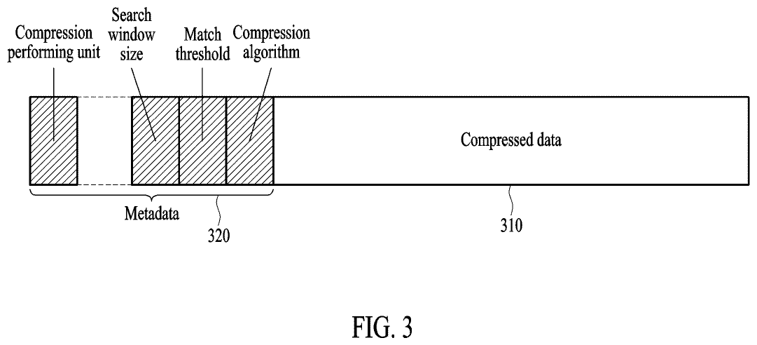

FIG. 3 illustrates an example of a form of compressed data. The description provided with reference to FIGS. 1 and 2 may also apply to FIG. 3.

Referring to FIG. 3, metadata 320 may be added in front of compressed data 310 according to an example. The metadata 320 may include parameter information used in a compression process and may provide information to be used to restore compressed data to an original state.

The metadata 320 according to an example may include various parameters such as a compression performing unit, the size of a search window, a match threshold, and a compression algorithm used. These parameters may provide information used to decompress the compressed data, thereby accurately restoring data during a restoration process. Each parameter may have a significant impact on performance during the compression process. For example, the size of the search window may determine a range in which duplicate data is found during compression, and the match threshold may specify the minimum length of a duplicate data block. These values may be repeatedly changed depending on intended performance of a system, and changed parameters may be recorded as the metadata 320.

The size of the metadata 320 may be very small compared to the size of the compressed data 310, and therefore overhead added due to the metadata 320 may not be large. Therefore, the presence of the metadata 320 may have a minimal impact on overall performance of the system, and efficient performance may be maintained during the compression and decompression processes.

When decompressing the compressed data, a decompression device (e.g., the decompression device 140 of FIG. 1) may set a compression algorithm and a parameter by referring to the metadata 320 and may perform accurate data restoration. Accordingly, the compression method and device of one or more embodiments may enable performance optimization during repeated compression and decompression processes and may provide flexibility for application to various systems.

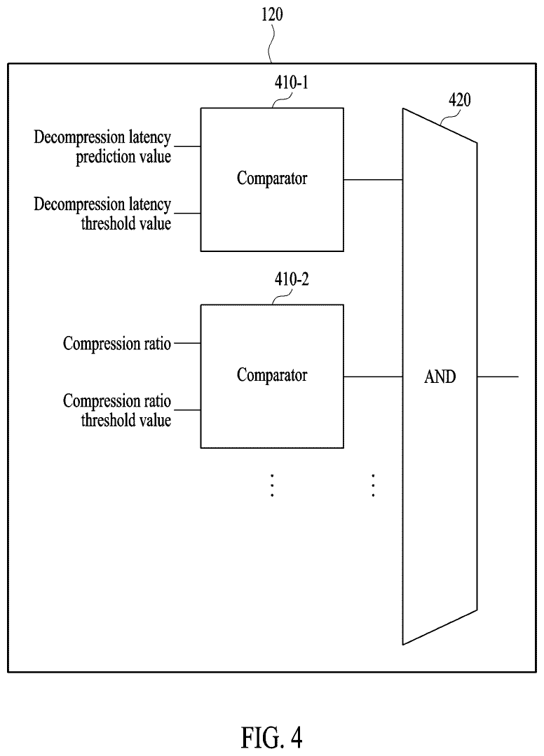

FIG. 4 illustrates an example of a configuration of a compression performance determination device. The description provided with reference to FIGS. 1 to 3 may also apply to FIG. 4.

Referring to FIG. 4, the compression performance determination device 120 according to an example may evaluate compression performance and may determine whether to perform additional compression. In order to determine whether to perform iterative compression, the compression performance determination device 120 may identify first a compression ratio and decompression latency after compression is performed. The compression ratio may be determined by comparing the size of compressed result data to the size of original data.

On the contrary, decompression latency may be often difficult to measure directly and may instead be predicted through determinations. Decompression latency prediction may vary depending on a compression algorithm used. Furthermore, the decompression latency prediction may vary depending on characteristics of the decompression device 140. Since decompression speed may vary depending on a decompression algorithm used by the decompression device 140, the decompression latency may be predicted based on this. For example, a compression algorithm of the LZ family may compress duplicate data into literal, length, and distance (LLD) blocks, and the decompression latency may be estimated based on the characteristics of this algorithm. A latency determination method may vary depending on a block shape of each algorithm, and in the present disclosure, the decompression latency may be predicted according to such an algorithm.

A comparator 410-1 may compare a decompression latency prediction value to a set threshold value and a comparator 410-2 may compare a compression ratio to another set threshold value. The comparator 410-1 may compare the decompression latency prediction value to a decompression latency threshold value, and the comparator 410-2 may compare the compression ratio to a compression ratio threshold value. As described above, the decompression latency threshold value and the compression ratio threshold value may be transmitted via an SFR according to an example. Although FIG. 4 shows that the decompression latency and the compression ratio are used as compression performance indices, various indices other than the compression ratio and the decompression latency may be used to evaluate the performance of a compression system, as described above. In this case, a comparator corresponding to each compression performance index may be used.

According to an example, results from the comparator 410-1 and the comparator 410-2 may be transmitted to an AND gate 420. The AND gate 420 may determine not to perform additional compression when both performance indices satisfy the threshold values. That is, the iterative compression may be terminated only when the decompression latency is less than the decompression latency threshold value and the compression ratio is greater than or equal to the compression ratio threshold value. On the contrary, when even one condition is not satisfied (e.g., when the decompression latency is greater than or equal to the decompression latency threshold value and/or the compression ratio is less than the compression ratio threshold value), it may be determined that the additional compression is to be performed, and an iterative compression condition changing device may be activated to change compression parameters and perform the compression again to optimize performance.

However, FIG. 4 shows only an example of the compression performance determination device 120, and the compression performance determination device 120 may be implemented in other forms. For example, the compression performance determination device 120 may be configured to transfer original data, not compressed data, to the memory 150 when both performance indices do not satisfy the threshold value.

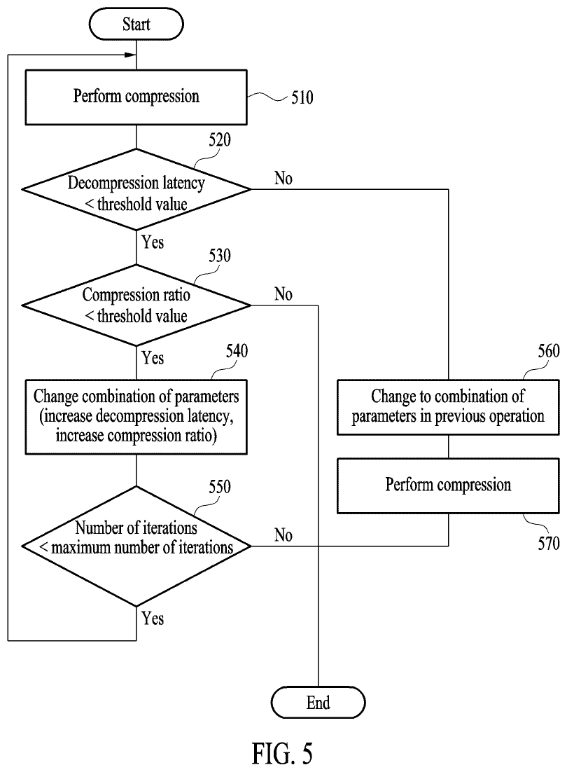

FIG. 5 illustrates an example of performing iterative compression based on performance of a compression ratio and decompression latency. The description provided with reference to FIGS. 1 to 4 may also apply to FIG. 5.

Operations 510 to 570 of FIG. 5 may be performed in the shown order and manner. However, the order of one or more of the operations may be changed, one or more of the operations may be omitted, two or more of the operations may be performed in parallel or simultaneously, and/or other operations may be additionally performed without departing from the spirit and scope of the example embodiments described herein.

Referring to FIG. 5, FIG. 5 shows in detail a process of performing iterative compression when an initial compression result has a compression ratio lower than a threshold value and decompression latency also lower than a threshold value.

The compression performance determination device 120 according to an example may perform compression in operation 510 and then may first compare whether decompression latency is less than a threshold value (e.g., the decompression latency threshold value), in operation 520. When the decompression latency is less than the threshold value, the compression performance determination device 120 may compare a compression ratio to another threshold value (e.g., the compression ratio threshold value), in operation 530.

When the compression ratio is less than the threshold value, the compression condition changing device 130 may adjust compression parameters such that the compression ratio may be increased, by changing a combination of parameters, in operation 540. During this process, the decompression latency may increase due to a trade-off relationship.

Subsequently, the compression condition changing device 130 may confirm whether the number of iterations has reached the maximum number of iterations, in operation 550. When the maximum number of iterations has not been reached, the compression device 110 may perform compression again with the changed parameters, and this process may be repeated until the compression ratio satisfies the threshold value.

However, when the decompression latency is greater than or equal to the threshold value during the iterative compression process in operation 520, the compression condition changing device 130 may revert to a previously used combination of parameters to optimize performance in operation 560. Here, the compression performance determination device 120 may change the combination of compression parameters to the combination of parameters used in a previous operation, in operation 560, and the compression device 110 may proceed with the compression again using the changed combination of compression parameters, in operation 570. To this end, the compression system may store the combination of parameters used in the previous operation.

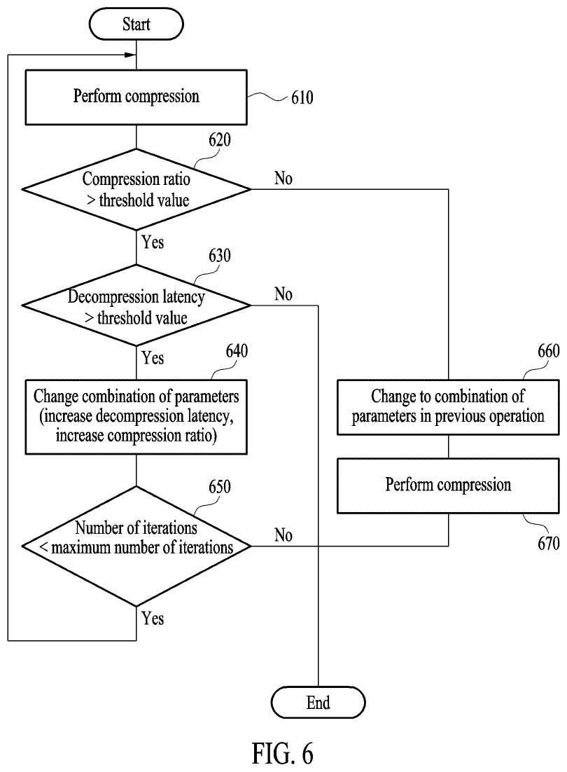

FIG. 6 illustrates another example of performing iterative compression based on performance of a compression ratio and decompression latency. The description provided with reference to FIGS. 1 to 4 may apply to FIG. 6 likewise. Operations 610 to 670 of FIG. 6 may be performed in the shown order and manner. However, the order of one or more of the operations may be changed, one or more of the operations may be omitted, two or more of the operations may be performed in parallel or simultaneously, and/or other operations may be additionally performed without departing from the spirit and scope of the example embodiments described herein.

Referring to FIG. 6, FIG. 6 shows in detail a process of performing iterative compression when an initial compression result has a compression ratio greater than a threshold value and decompression latency also greater than a threshold value.

The compression performance determination device 120 according to an example may perform compression in operation 610 and then may first compare whether a compression ratio is greater than a threshold value (e.g., the compression ratio threshold value), in operation 620. When the compression ratio is greater than the threshold value, the compression performance determination device 120 may compare whether decompression latency is greater than another threshold value (e.g., the decompression latency threshold value), in operation 630.

When the decompression latency is greater than the threshold value, the compression condition changing device 130 may change a combination of parameters and may adjust compression parameters such that the decompression latency is reduced, in operation 640. During this process, the compression ratio may decrease due to a trade-off relationship.

Subsequently, the compression condition changing device 130 may confirm whether the number of iterations has reached the maximum number of iterations, in operation 650. When the maximum number of iterations has not been reached, the compression device 110 may perform compression again with the changed parameters, and this process may be repeated until the compression ratio satisfies the threshold value.

However, when the compression ratio is less than or equal to the threshold value during the iterative compression process in operation 630, the compression condition changing device 130 may change the combination of compression parameters to the combination of parameters used in a previous operation, in operation 660, and the compression device 110 may proceed with the compression again using the changed combination of compression parameters, in operation 670. To this end, the compression system may store the combination of parameters used in the previous operation.

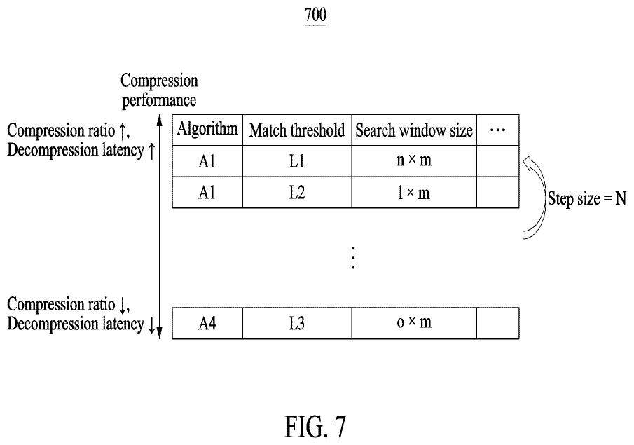

FIG. 7 illustrates an example of a table representing a combination of compression parameters. The description provided with reference to FIGS. 1 to 6 may also apply to FIG. 7.

Referring to FIG. 7, a compression parameter combination table 700 according to an example may provide combinations including various parameters such as a compression algorithm, a compression performing unit, a match threshold, and a search window and may be used as a tool for predicting an impact on compression performance in advance. The compression parameter combination table 700 may have a structure that considers performance of each combination, and a combination may be selected according to desired or intended performance.

Before the compression is performed, an initial parameter combination may be set depending on intended performance (e.g., a predetermined intended performance). When the performance is not satisfied after the compression is performed, the compression condition changing device 130 may be used to switch to another parameter combination in the table. A parameter combination may be changed in a manner of moving according to a predetermined step size in the compression parameter combination table 700. When a compression ratio is to be increased, a combination at the top of the table may be selected, and when decompression latency is to be decreased, a combination at the bottom may be selected.

In addition, a performance difference when changing the parameter combination may be an important standard for selecting a parameter combination to be used in the next iteration compression. The compression condition changing device 130 may control performance changes by adjusting the step size. For example, the compression condition changing device 130 may finely adjust performance by setting a large step size when a larger performance change is desired and reducing the step size when a smaller performance change is desired.

When the number of parameter combinations is less than the maximum number of iterations, optimal performance may be achieved by applying as many combinations as possible. However, when the number of parameter combinations exceeds the maximum number of iterations, it may become difficult to find an optimal combination and the iteration may be stopped. In this case, a binary search technique or a method of determining a step size considering the maximum number of iterations by setting upper and lower limits may be used.

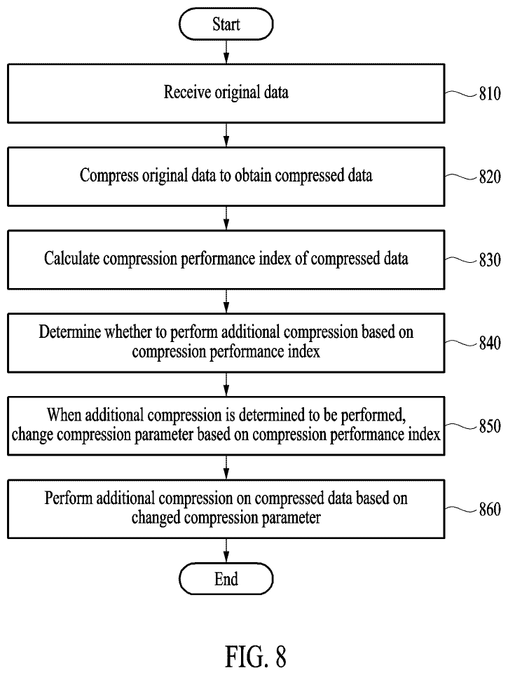

FIG. 8 illustrates an example of a compression method. The description provided with reference to FIGS. 1 to 7 may also apply to FIG. 8.

Operations 810 to 860 of FIG. 8 may be performed in the shown order and manner. However, the order of one or more of the operations may be changed, one or more of the operations may be omitted, two or more of the operations may be performed in parallel or simultaneously, and/or other operations may be additionally performed without departing from the spirit and scope of the example embodiments described herein.

Referring to FIG. 8, in operation 810, the compression device 110 according to an example may receive original data. The compression device 110 may receive the original data from the host 100.

In operation 820, the compression device 110 according to an example may compress the original data to generate compressed data.

In operation 830, the compression performance determination device 120 according to an example may determine a compression performance index of the compressed data. The compression performance determination device 120 may determine a compression ratio of the compressed data and decompression latency of the compressed data.

In operation 840, the compression performance determination device 120 according to an example may determine whether to perform additional compression based on the compression performance index. The compression performance determination device 120 may compare the compression performance index to a threshold value and based on a comparison result, may determine whether to perform the additional compression. The compression performance determination device 120 may compare the compression ratio of the compressed data to a first threshold value and may compare the decompression latency of the compressed data to a second threshold value. The compression performance determination device 120 may determine not to perform the additional compression when the compression ratio is greater than or equal to the first threshold value and the decompression latency is less than or equal to the second threshold value.

In operation 850, when the additional compression is determined to be performed, the compression condition changing device 130 according to an example may change a compression parameter based on the compression performance index. The compression condition changing device 130 may change at least one of a compression algorithm, a compression performing unit, a match threshold, and/or a search window.

In operation 860, the compression device 110 according to an example may perform the additional compression on the compressed data based on the changed compression parameter.

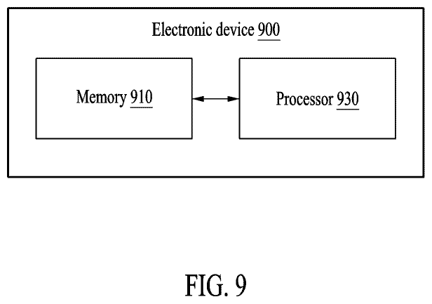

FIG. 9 illustrates an example of an electronic device. The description provided with reference to FIGS. 1 to 8 may apply to FIG. 9 likewise. For example, an electronic device 900 may include a compression system described with reference to FIG. 1.

Referring to FIG. 9, the electronic device 900 according to an example may include a memory 910 (e.g., one or more memories) and a processor 930 (e.g., one or more processors).

The memory 910 may store instructions (or programs) executable by the processor 930. For example, the instructions include instructions for performing an operation of the processor 930 and/or an operation of each component of the processor 930. For example, the memory 910 may be or include a non-transitory computer-readable storage medium storing code that, when executed by the processor 930, configures the processor 930 to perform any one, any combination, or all of the operations and/or methods disclosed herein with reference to FIGS. 1-8.

The memory 910 may be implemented as a volatile memory device or a non-volatile memory device.

The volatile memory device may be implemented as dynamic random-access memory (DRAM), static random-access memory (SRAM), thyristor RAM (T-RAM), zero capacitor RAM (Z-RAM), and/or twin transistor RAM (TTRAM).

The non-volatile memory device may be implemented as electrically erasable programmable read-only memory (EEPROM), flash memory, magnetic RAM (MRAM), spin-transfer torque (STT)-MRAM, conductive bridging RAM (CBRAM), ferroelectric RAM (FeRAM), phase-change RAM (PRAM), resistive RAM (RRAM), nanotube RRAM, polymer RAM (PoRAM), nano floating gate memory (NFGM), holographic memory, a molecular electronic memory device, and/or insulator resistance change memory.

The processor 930 may process data stored in the memory 910. The processor 930 may execute computer-readable code (e.g., software) stored in the memory 910, and instructions triggered by the processor 930.

The processor 930 may be a data processing device implemented by hardware including a circuit having a physical structure to perform desired operations. For example, the desired operations may include code or instructions in a program.

The hardware-implemented data processing device may include, for example, a microprocessor, a central processing unit (CPU), a processor core, a multi-core processor, a multiprocessor, an application-specific integrated circuit (ASIC), and a field-programmable gate array (FPGA).

The processor 930 may perform operations of the compression system described with reference to FIGS. 1 to 8 in substantially the same manner. Accordingly, a further description thereof will be omitted herein.

The hosts, compression devices, compression performance determination devices, compression condition changing devices, decompression devices, memories, comparators, AND gates, electronic devices, processors, host 100, compression device 110, compression performance determination device 120, compression condition changing device 130, decompression device 140, memory 150, comparator 410-1, comparator 410-2, AND gate 420, electronic device 900, memory 910, and processor 930 described herein, including descriptions with respect to respect to FIGS. 1-9, are implemented by or representative of hardware components. As described above, or in addition to the descriptions above, examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. As described above, or in addition to the descriptions above, example hardware components may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in, and discussed with respect to, FIGS. 1-9 that perform the operations described in this application are performed by computing hardware, for example, by one or more processors or computers, implemented as described above implementing instructions (e.g., computer or processor/processing device readable instructions) or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media, and thus, not a signal per se. As described above, or in addition to the descriptions above, examples of a non-transitory computer-readable storage medium include one or more of any of read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as multimedia card micro or a card (for example, secure digital (SD) or extreme digital (XD)), magnetic tapes, floppy disks, magneto-optical data storage devices, optical data storage devices, hard disks, solid-state disks, and/or any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above and all drawing disclosures, the scope of the disclosure is also inclusive of the claims and their equivalents, i.e., all variations within the scope of the claims and their equivalents are to be construed as being included in the disclosure.

What is claimed is:

1. A processor-implemented method comprising:
receiving original data;
obtaining compressed data by compressing the original data;
determining a compression performance index of the compressed data;
determining whether to perform additional compression based on the compression performance index;
in response to determining that the additional compression is to be performed, changing a compression parameter based on the compression performance index; and
performing the additional compression on the compressed data based on the changed compression parameter.

2. The method of claim 1, wherein the determining of whether to perform the additional compression comprises:
comparing the compression performance index to a threshold value; and
based on a result of the comparing, determining whether to perform the additional compression.

3. The method of claim 1, wherein the determining of the compression performance index comprises:
determining a compression ratio of the compressed data; and
determining decompression latency of the compressed data.

4. The method of claim 3, wherein the determining of whether to perform the additional compression comprises:
comparing the compression ratio of the compressed data to a first threshold value; and
comparing the decompression latency of the compressed data to a second threshold value.

5. The method of claim 4, wherein the determining of whether to perform the additional compression comprises determining not to perform the additional compression in response to the compression ratio being greater than the first threshold value and the decompression latency being less than or equal to the second threshold value.

6. The method of claim 4, wherein the determining of whether to perform the additional compression comprises determining to perform the additional compression in response to either one or both of:
the compression ratio being less than the first threshold value; and
the decompression latency being greater than or equal to the second threshold value.

7. The method of claim 4, wherein
the determining of whether to perform the additional compression comprises determining to perform the additional compression in response to the compression ratio being less than the first threshold value and the decompression latency being less than the second threshold value, and
the changing of the compression parameter comprises changing the compression parameter such that the compression ratio increases.

8. The method of claim 4, wherein
the determining of whether to perform the additional compression comprises determining to perform the additional compression in response to the compression ratio being greater than or equal to the first threshold value and the decompression latency being greater than or equal to the second threshold value, and
the changing of the compression parameter comprises changing the compression parameter such that the compression latency decreases.

9. The method of claim 4, wherein
the determining of whether to perform the additional compression comprises determining to perform the additional compression in response to the compression ratio being less than the first threshold value and the decompression latency being greater than or equal to the second threshold value, and
the changing of the compression parameter comprises:
determining a priority between the compression ratio and the decompression latency; and
changing the compression parameter based on the priority.

10. The method of claim 3, wherein the determining of the compression ratio comprises determining the compression ratio by comparing a size of the original data to a size of the compressed data.

11. The compression method of claim 3, wherein the determining of the decompression latency comprises determining the decompression latency based on characteristics of a compression algorithm and a decompression device.

12. The method of claim 1, wherein the changing of the compression parameter comprises changing any one or any combination of any two or more of a compression algorithm, a compression performing unit, a match threshold, and a search window.

13. The method of claim 1, wherein the changing of the compression parameter comprises:
setting a combination of compression parameters based on any one or any combination of any two or more of a compression algorithm, a compression performing unit, a match threshold, and a search window; and
determining the combination of compression parameters, based on the compression performance index.

14. An electronic device comprising:
one or more processors configured to:
receive original data;
obtain compressed data by compressing the original data;
determine a compression performance index of the compressed data;
determine whether to perform additional compression based on the compression performance index;
in response to determining that the additional compression is to be performed, change a compression parameter based on the compression performance index; and
perform the additional compression on the compressed data based on the changed compression parameter.

15. The electronic device of claim 14, wherein, for the determining of whether to perform the additional compression, the one or more processors are configured to:
compare the compression performance index to a threshold value; and
based on a result of the comparing, determine whether to perform the additional compression.

16. The electronic device of claim 14, wherein, for the determining of the compression performance index, the one or more processors are configured to:
determine a compression ratio of the compressed data; and
determine decompression latency of the compressed data.

17. The electronic device of claim 16, wherein, for the determining of whether to perform the additional compression, the one or more processors are configured to:
compare the compression ratio of the compressed data to a first threshold value; and
compare the decompression latency of the compressed data to a second threshold value.

18. The electronic device of claim 17, wherein, for the determining of whether to perform the additional compression, the one or more processors are configured to determine not to perform the additional compression in response to the compression ratio being greater than or equal to the first threshold value and the decompression latency being less than the second threshold value.

19. The electronic device of claim 14, wherein, for the changing of the compression parameter, the one or more processors are configured to:
set a combination of compression parameters based on any one or any combination of any two or more of a compression algorithm, a compression performing unit, a match threshold, and a search window; and
determine the combination of the compression parameters based on the compression performance index.

20. A processor-implemented method comprising:
determining a compression ratio and a decompression latency of compressed data;
in response to either one or both of the compression ratio being less than a first threshold value and the decompression latency being greater than or equal to a second threshold value, changing a compression parameter; and
performing additional compression on the compressed data based on the changed compression parameter.
